(19) United States
(12) Patent Application Publication
(10) Pub. No.: US 2013/0167920 A1
(43) Pub. Date: Jul. 4, 2013

(54) CONDUCTIVE SUBSTRATE AND FABRICATING METHOD THEREOF, AND SOLAR CELL

(71) Applicants: Chia-Chiang Chang, Taoyuan County (TW); Chin-Jyi Wu, Kaohsiung City (TW); Chun-Hsien Su, Hsinchu City (TW); Dao-Yang Huang, Hsinchu City (TW)

(72) Inventors: Chia-Chiang Chang, Taoyuan County (TW); Chin-Jyi Wu, Kaohsiung City (TW); Chun-Hsien Su, Hsinchu City (TW); Dao-Yang Huang, Hsinchu City (TW)

(73) Assignees: BAY ZU PRECISION CO., LTD., Tainan City (TW); INDUSTRIAL TECHNOLOGY RESEARCH INSTITUTE, Hsinchu (TW)

(21) Appl. No.: 13/567,106

(22) Filed: Aug. 6, 2012

(30) Foreign Application Priority Data
Dec. 28, 2011 (TW) 100149271

(51) Int. Cl. H01L 31/0236; C23C 14/34; B32B 3/30; H01L 31/18

(52) U.S. Cl. 136/256; 438/71; 204/192.1; 428/141; 257/E31.13

(57) ABSTRACT

A fabricating method of a conductive substrate including the following steps is provided. A substrate is provided. A barrier layer having a first roughened surface is formed on the substrate by an atmospheric pressure plasma process, wherein the surface roughness (Ra) of the first roughened surface formed by the atmospheric pressure plasma process is between 10 nanometers (nm) and 100 nm. A first electrode layer is formed on the first roughened surface of the barrier layer by a vacuum sputter process, wherein a second roughened surface with the surface roughness (Ra) between 10 nm and 100 nm is formed on a surface of the first electrode layer. Furthermore, a photoelectric conversion layer is formed on the second roughened surface of the first electrode layer. A second electrode layer is formed on the photoelectric conversion layer. A solar cell and a conductive substrate are also provided.

### CROSS-REFERENCE TO RELATED APPLICATION

This application claims the priority benefit of Taiwan application serial no. 100149271, filed on Dec. 28, 2011. The entirety of the above-mentioned patent application is hereby incorporated by reference herein and made a part of this specification.

### BACKGROUND

1. Technical Field

The present disclosure relates to a conductive substrate, a fabricating method thereof, a solar cell comprising the same, and more particularly to a conductive glass substrate having a barrier layer with a roughened surface, a fabricating method thereof, and a solar cell comprising the same.

2. Related Art

The “energy” already becomes one of the important subjects that urgently require developing and solving nowadays. However, currently the petrochemical energy gradually gets exhausted and the overuse of the petrochemical energy also causes severe pollution problems. Therefore, the exploitation and use of low-pollution renewable energy becomes the only way for people to seek sustainable development. Currently, the sources of the renewable energy mainly include: solar energy, wind energy, water energy, tidal energy, terrestrial heat, and bio-energy. In the various types of energies, the solar energy gains the most attention, because this type of energy is most abundant and the exploitation and application thereof is not limited by the factors such as landform and topography. Further, the solar energy can be directly converted into the commonly usable electric power through a suitable apparatus or device. The apparatus or device is the so-called “solar cell”.

In recent years, to enhance the photoelectric conversion efficiency of the solar cell, a conventional solar cell technology is to use the thermal cracking manner to roughen transparent conductive oxide (TCO) glass and perform a spraying work when the glass comes out from the furnace. As the waste heat of the furnace is used for processing, the production cost can be reduced to the minimum. However, a spraying material forms strong acids resulting in fairly high cost subsequent processing and high maintenance cost of the apparatus. Also, such a process is unable to make detailed adjustments of the structure.

In a further conventional solar cell technology, an electrode film is formed first by using the vacuum sputtering, wet etching is then performed by using the diluted hydrochloric acid, a surface of the electrode film after the wet etching is formed with a porous structure, and with such a structure, the function of scattering light is obtained. However, such a process is complicated and has a high cost for mass production, and also in the wet etching method, it is not easy to control the etching evenness of the surface with a large area.

Therefore, to seek a solar cell which has a simpler process, is more power saving and environmentally friendly and enable the solar cell to reach higher photoelectric conversion efficiency already becomes one of very important developing directions in the relevant fields of solar cell at present.

### SUMMARY

The present disclosure provides a fabricating method of a conductive substrate, which include the following steps. A substrate is provided. A barrier layer having a first roughened surface is formed on the substrate by an atmospheric pressure plasma process, wherein the surface roughness (Ra) of the first roughened surface formed by the atmospheric pressure plasma process is between 10 nanometer (nm) and 100 nm. A first electrode layer is formed on the first roughened surface of the barrier layer by a vacuum sputter process, and a second roughened surface with the surface roughness (Ra) between 10 nm and 100 nm is formed on a surface of the first electrode layer. Furthermore, the second roughened surface is formed according to a surface feature (topography) of the first roughened surface for forming the first electrode layer in the vacuum sputter process.

The present disclosure further provides a conductive substrate, which includes a substrate, a barrier layer, and a first electrode layer. The barrier layer is located on the substrate and has a first roughened surface, and the surface roughness (Ra) of the first roughened surface is between 10 nm and 100 nm. The first electrode layer covers the first roughened surface of the barrier layer and has a second roughened surface, and the surface roughness (Ra) of the second roughened surface is between 10 nm and 100 nm. Furthermore, the second roughened surface is formed according to a surface feature of the first roughened surface.

The present disclosure further provides a solar cell, which includes a substrate, a barrier layer, a first electrode layer, a photoelectric conversion layer, and a second electrode layer. The barrier layer is located on the substrate and has a first roughened surface, and the surface roughness (Ra) of the first roughened surface is between 10 nm and 100 nm. The first electrode layer covers the first roughened surface of the barrier layer and has a second roughened surface, and the surface roughness (Ra) of the second roughened surface is between 10 nm and 100 nm. Furthermore, the second roughened surface is formed according to a surface feature of the first roughened surface. The photoelectric conversion layer is located on the second roughened surface of the conductive glass. The second electrode layer is located on the photoelectric conversion layer.

Based on the above, in the fabricating method of a conductive substrate according to the present disclosure, when a barrier layer is formed on a substrate by the atmospheric pressure plasma, a first roughened surface having the specific roughness is directly formed on the surface of the barrier layer. Therefore, for the first electrode layer deposited thereon subsequently, the second roughened surface is immediate formed during the film forming of the first electrode layer according to the surface feature of the first roughened surface of the barrier layer in the film forming process.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a sectional view of a conductive substrate according to an embodiment of the present disclosure.

FIG. 2A to FIG. 2E are schematic flow charts of a fabricating method of a conductive substrate and a solar cell according to an embodiment of the present disclosure.

FIG. 3A and FIG. 3B are scanning electron microscope (SEM) pictures of forming a barrier layer and a first electrode layer on a substrate of a conductive substrate according to the present disclosure.

FIG. 4A is a SEM picture of an electrode layer having a surface with a porous structure formed through wet etching after an electrode film is formed for a conventional conductive substrate.

FIG. 4B is a SEM picture of a second roughened surface directly formed without etching after a first electrode layer film is formed in a conductive substrate according to the present disclosure.

FIG. 5 is a schematic view of a conductive substrate according to an embodiment of the present disclosure.

FIG. 6 is a chart of the relationship between the haze of a conductive substrate and the surface roughness of a first electrode layer according to the present disclosure.

FIG. 7 shows the relationship between the resistivity and the second heating temperature of a conductive substrate fabricated when a substrate and a barrier layer are heated at different second heating temperatures in the conductive substrate according to an embodiment of the present disclosure.

### DETAILED DESCRIPTION OF DISCLOSED EMBODIMENTS

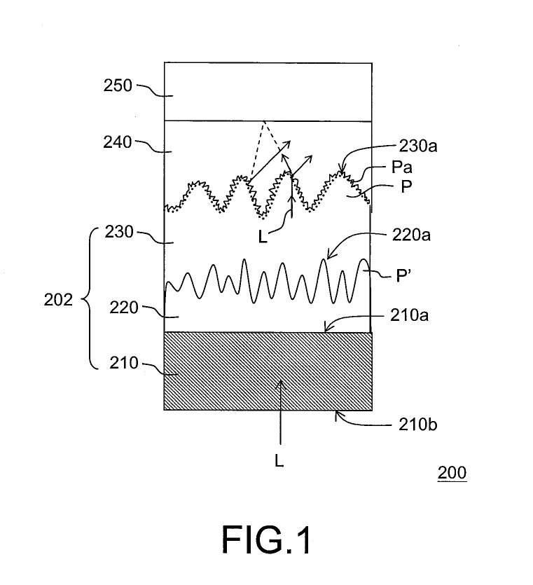

FIG. 1 is a sectional view of a solar cell fabricated according to an embodiment of the present disclosure. A solar cell 200 includes a conductive substrate 202, which includes a substrate 210, a barrier layer 220, and a first electrode layer 230. In an application example of the solar cell, a solar cell 200 is formed further with a photoelectric conversion layer 240 and a second electrode layer 250. As shown in FIG. 1, the substrate 210 has a first surface 210a and a second surface 210b. A barrier layer 220, a first electrode layer 230, a photoelectric conversion layer 240, and a second electrode layer 250 are stacked on a first surface 210a of the substrate 210 in sequence. The photoelectric conversion layer 240 in this embodiment includes the stack of a PIN structure in sequence or the stack of a NIP structure in sequence on the first electrode layer 230. Particularly, in the solar cell 200 in this embodiment, a surface of the barrier layer 220 toward the photoelectric conversion layer 240 of the conductive substrate 202 is a first roughened surface 220a having the specific roughness directly formed in the film forming of the barrier layer 220. Therefore, the first electrode layer 230 can directly use the first roughened surface 220a as the basal plane for grain growth during the subsequent film forming. In other words, a topography (surface feature, morphology) of the second roughened surface 230a of the first electrode layer 230 is formed according to a topography (morphology) of the first roughened surface 220a of the barrier layer 220, so that after the film forming of the first electrode layer 230, a second roughened surface 230a having roughness is directly formed at a surface.

Also, as shown in FIG. 1, multiple projections P (the dotted line profile depicted in FIG. 1) exist on the second roughened surface 230a of the first electrode layer 230. Particularly, as the second roughened surface 230a of the first electrode layer 230 is formed according to the topography of the first roughened surface 220a of the barrier layer 220 rather than formed by an etching process, multiple micro-projections Pa (the zigzag micro-projections Pa located outside the dotted line profile in FIG. 1) further exist on the projections P of the second roughened surface 230a. In such a manner, when a light ray L (for example, sun light) enters the solar cell 200 through the second surface 210b of the substrate 210, the second roughened surface 230a having the projections P of the first electrode layer 230 can enable the light ray L to successfully enter the photoelectric conversion layer 240, so as to reduce the reflection losses and enable the light ray L to be refracted and reflected multiple times in the photoelectric conversion layer 240, thereby increasing the absorbing path of the light ray L in the photoelectric conversion layer 240 to form a light-trapping effect and further enhancing the photoelectric conversion efficiency of the solar cell 200. Furthermore, the micro-projections Pa on the projections P of the second roughened surface 230a may further contribute a lot to the light-trapping effect.

In the following, the fabricating method of the solar cell 200 fabricated with the conductive substrate 202 of the present disclosure is illustrated in detail.

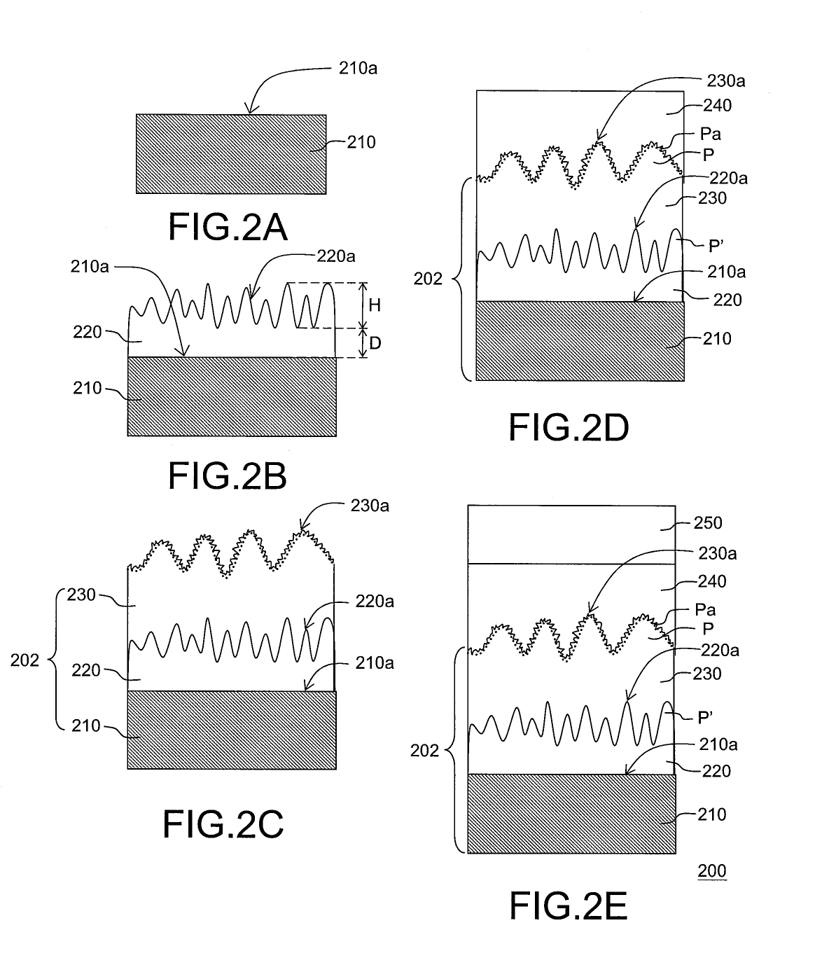

FIG. 2A to FIG. 2E are schematic flow charts of fabricating methods of a conductive substrate and a solar cell according to an embodiment of the present disclosure. Referring to FIG. 2A first, a substrate 210 is provided first, wherein the substrate 210 may be a transparent substrate 210, and a material thereof may be glass, transparent resin or other suitable transparent materials. The transparent resin is, for example, polyethylene terephthalate (PET), polyethylene naphthalate (PEN), polycarbonate (PC), polyethersulfone (PES), and polyimide (PI). No roughening processing such as etching is performed on the first surface 210a of the substrate 210, and a flat and non-roughened surface is thus obtained.

Next, a barrier layer 220 is formed on the first surface 210a of the substrate 210 by an atmospheric pressure plasma process. In the present disclosure, the atmospheric pressure plasma process is Atmospheric Pressure Plasma Enhanced Chemical Vapor Deposition (APPECVD). In the “atmospheric pressure plasma process”, a “pressure close to the atmospheric pressure” is used to represent a range from 650 Torr to 800 Torr. Although mixed gas such as the air can be used as the discharge gas when the atmospheric pressure plasma process occurs, it is better to use at least one of nitrogen, oxygen, clean dry air (CDA), and mixed gas of nitrogen and oxygen. A material of the barrier layer 220 is, for example, silicon oxide (SiOx, x is about 2).

In the present disclosure, when the barrier layer 220 is formed on the substrate 210 with the process characteristic that a film layer with the small thickness and high roughness can be easily formed by the atmospheric pressure plasma process, the first roughened surface 220a having small thickness and fair roughness can be obtained after the film forming process. In particular, in this embodiment, the barrier layer 220 formed by the atmospheric pressure plasma process can have the thickness, for example, between 10 nm and 50 nm and the surface roughness Ra between 10 nm and 100 nm. In other words, as shown in FIG. 2B, the maximum height H of the projection P on the first roughened surface 220a formed by the atmospheric pressure plasma process may be greater than the thickness D of the continuous phase portion of the barrier layer 220. Also, as shown in FIG. 2B, the other surface opposite to the first roughened surface 220a of the barrier layer 220 is a flat surface. That is, the surface where the barrier layer 220 abuts the substrate 210 has the same configuration as the first surface 210a of the substrate 210, which are both non-roughened flat surface.

Furthermore, in the film forming process of the barrier layer 220 by the atmospheric pressure plasma process, multiple dielectric particulates separated from each other are first formed on the substrate 210. Each dielectric particulate gradually grows into a dielectric particle in the atmospheric pressure plasma process until these dielectric particles adjacently join into a whole barrier layer 220. Therefore, the barrier layer 220 having the first roughened surface 220a in the present application is formed of multiple adjacent dielectric particles joining together instead of film forming followed by roughening through the etching process.

It should be noted that before the barrier layer 220 is formed on the substrate 210 by the atmospheric pressure plasma process, a heating process can be first performed on the substrate 210 to enhance the quality of film forming of the barrier layer 220. For example, the substrate 210 can be heated at the first heating temperature to increase the temperature of the substrate 210 to the first heating temperature, so that the atmospheric pressure plasma process of the substrate 210 takes place at the first heating temperature to deposit the barrier layer 220 on the substrate 210 having the first heating temperature. The range of the first heating temperature is, for example, higher than room temperature and lower than 100° C., and is better between 40° C. and 70° C.

Subsequently, as shown in FIG. 2C, by a vacuum sputter process, a first electrode layer 230 is formed on the first roughened surface 220a of the barrier layer 220, wherein a material of the first electrode layer 230 can be TCO, for example, indium tin oxide (ITO), indium zinc oxide (ZnO) (IZO), Al doped ZnO (AZO) (ZnO:Al), Ga doped ZnO (GZO) (ZnO:Ga) or Ga—Al-doped ZnO (GAZO) (ZnO:Ga,Al) or other transparent conductive materials. Particularly, a second roughened surface 230a is directly formed of the first electrode layer 230 in the vacuum sputter process according to a topography (morphology) of the first roughened surface 220a, that is, a conductive substrate 202 is formed. In the vacuum sputter process in this embodiment, different regions of the first roughened surface 220a are used as seed grains with different grain growth speeds in the film forming of the first electrode layer 230, so that the second roughened surface 230a is directly formed at the surface after the film forming of the first electrode layer 230. In a conventional solar cell, after the electrode film is formed, different porous structures are further formed through the wet etching. Compared with the conventional one, the wet etching process can be omitted for the solar cell 200 of the present disclosure, and the problem that in the wet etching it is not easy to control the surface etching evenness can be avoided.

In other words, in the present disclosure, with the process characteristic that a film layer with a fairly high coverage rate is easily formed by the vacuum sputter process, in the film forming of the first electrode layer 230 by the vacuum sputter process, the first electrode layer 230 having the second roughened surface 230a is directly obtained after the film forming. Therefore, in the present disclosure, in combination with the atmospheric pressure plasma process, the characteristic of the barrier layer 220 having the characteristic of the first roughened surface 220a can be formed. In combination with the vacuum sputter process, based on the characteristic of the first roughened surface 220a, the characteristic of the first electrode layer 230 having the second roughened surface 230a can be directly formed. Therefore, through the second roughened surface 230a of the first electrode layer 230 obtained by the above process, the characteristic of light scattering can be achieved. In such a manner, as discussed above, when a light ray L (for example, sun light) enters the solar cell 200 through the second surface 210b of the substrate 210, the second roughened surface 230a having the projections P of the first electrode layer 230 can enable the light ray L to successfully enter the photoelectric conversion layer 240, so as to reduce the reflection losses and enable the light ray L to be refracted and reflected multiple times in the photoelectric conversion layer 240, thereby increasing the absorbing path of the light ray L, forming a light-trapping effect, and further enhancing the photoelectric conversion efficiency of the solar cell 200.

Furthermore, the second roughened surface 230a of the first electrode layer 230 is formed according to the topography (morphology) of the first roughened surface 220a in the vacuum sputter process without any etching process. Therefore, micro-projections Pa (zigzag micro-projections Pa located outside the dotted line profile in FIG. 2A) that further grow on each projection P due to extrusion among dielectric particles in the growth in the film forming can be kept on each projection P of the second roughened surface 230a rather than being removed by the etching process. Therefore, the roughened microstructures at the surface of the first electrode layer 230 of the conductive substrate 202 formed by using the fabricating method of the present disclosure are different from the porous structures formed through wet etching after the electrode film is formed for the transparent conductive substrate used in a conventional solar cell. It should be noted that the micro-projections Pa located on each projection P of the second roughened surface 230a have smaller scales, so as to further reduce the reflection amount of the light and increase the probability that the light ray L is scattered in the solar cell 200, thereby increasing the travel distance of the incident light in the photoelectric conversion layer 240 and enhancing a light-trapping effect of the solar cell 200.

It should be noted that before the first electrode layer 230 is formed on the barrier layer 220 by the vacuum sputter process, the heating process can be performed on the substrate 210 first to enhance the quality of film forming of the first electrode layer 230. For example, the substrate 210 can be heated at the second heating temperature to increase the temperature of the substrate 210 to the second heating temperature, so that the vacuum sputter process of the substrate 210 takes place at the second heating temperature, thereby depositing the first electrode layer 230 on the substrate 210 having the second heating temperature. The range of the second heating temperature is, for example, between 250° C. and 450° C., and is better between 300° C. and 400° C. (illustrated below).

By using the above atmospheric pressure plasma process, the characteristic of the first roughened surface 220a of the formed barrier layer 220 can be controlled, so as to control the basal plane underneath when the first electrode layer 230 is being formed, and by the vacuum sputter process, the structure feature of the second roughened surface 230a of the formed first electrode layer 230 can be controlled, so as to obtain the first electrode layer 230 having different surface characteristics, thereby generating the conductive substrate 202 having specific characteristics (illustrated below). Also, when the conductive substrate 202 is combined with the subsequent photoelectric conversion layer 240 and second electrode, the power generating efficiency can be enhanced.

Subsequently, the conductive substrate of the present disclosure is applied to the solar cell. As shown in FIG. 2D, the photoelectric conversion layer 240 is formed on the second roughened surface 230a of the first electrode layer 230. The photoelectric conversion layer 240 is disposed on the first electrode layer to serve as an active layer. The photoelectric conversion layer 240 may be a single-layer structure or a tandem structure. In this embodiment, a silicon based solar cell is taken as an example, but the present disclosure is not limited thereto. A material of the photoelectric conversion layer 240 is, for example, amorphous silicon (a-Si layer), microcrystalline silicon or a multi-layered structure stacked by the above materials. In an embodiment, the photoelectric conversion layer 240 may be a PIN semiconductor stack structure having a P-type semiconductor layer, an N-type semiconductor layer, and an intrinsic layer, or a PN semiconductor stack structure without an intrinsic layer. In the present disclosure, the number or structure of photoelectric conversion material layers used in the photoelectric conversion layer 240 is not limited, and persons of ordinary skill in the art can make adjustments according to demands.

Next, as shown in FIG. 2E, a second electrode layer 250 is formed on the photoelectric conversion layer 240. The second electrode layer 250 is disposed on the photoelectric conversion layer 240 to serve as another electrode opposite to the first electrode layer 230. A material and a forming method of the second electrode layer 250 can be the same as those of the above first electrode layer 230. For example, both the electrode layers may use the transparent electrode made of ZnO doped with other materials, such as AZO and GZO. Of course, a material of the second electrode layer 250 may also be an opaque metal material to form an opaque electrode. The present disclosure is not limited thereto, which depends on the product demands.

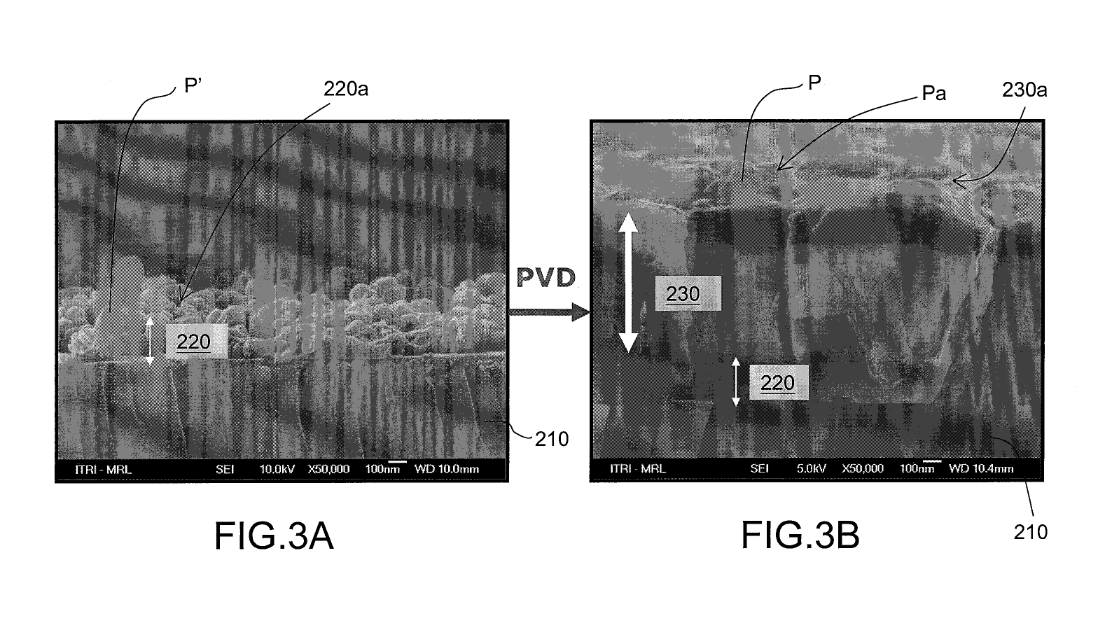

FIG. 3A and FIG. 3B are SEM pictures of forming a barrier layer on a substrate and forming a first electrode layer on a barrier layer in a solar cell using a conductive substrate of the present disclosure, respectively. Particularly, in FIG. 3A, a surface of a barrier layer 220 formed on the substrate 210 by using the APPECVD presents the smooth projections P′ in FIG. 2B, so as to further form a first roughened surface 220a. In FIG. 3B, the first electrode layer 230 further grows on the barrier layer 220 having the first roughened surface 220a by the vacuum sputter process, so that the first electrode layer 230 is formed with the second roughened surface 230a having the projections P, and also, multiple micro-projections Pa are further formed on each projection P. Through the projections P and even the micro-projections Pa on the second roughened surface 230a of the first electrode layer 230, the photoelectric conversion efficiency of the solar cell 200 can be further enhanced.

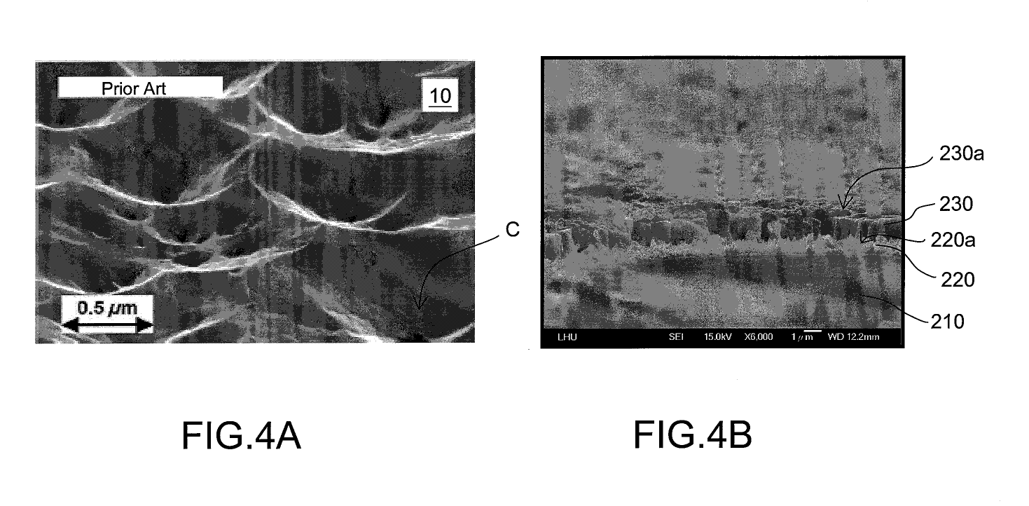

Furthermore, FIG. 4A is a SEM picture of an electrode layer having a surface of a porous structure formed by wet etching after an electrode film is formed in a conventional solar cell. FIG. 4B is a SEM picture of a second roughened surface formed directly without etching after film forming of a first electrode layer in a solar cell using a conductive substrate of the present disclosure. As can be seen from FIG. 4A and FIG. 4B, a second roughened surface 230a of a first electrode layer 230 fabricated by using a fabricating method of a conductive substrate of the present disclosure is shown in FIG. 4B, which has a relatively high projection density. On the contrary, the conventional structure after roughening the surface of the electrode layer 10 after the film forming through wet etching is shown in FIG. 4A, which has a low density of concaves C. In other words, compared with the electrode layer surface fabricated using the conventional technology, the second roughened surface 230a of the first electrode layer 230 fabricated by using the fabricating method of a conductive substrate of the present disclosure has higher projection density and higher roughness. Therefore, by using the fabricating method of the solar cell 200 having the conductive substrate according to the present disclosure, the solar cell 200 with higher photoelectric conversion efficiency can be fabricated through a simpler process.

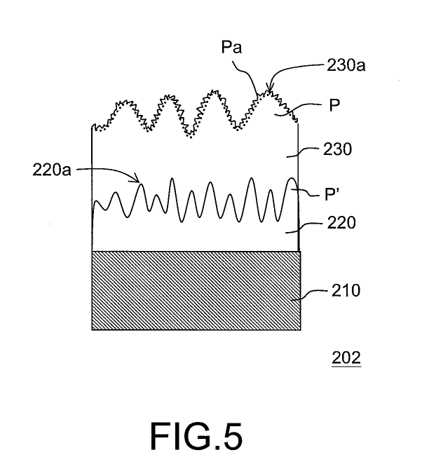

FIG. 5 is a schematic view of a conductive substrate according to an embodiment of the present disclosure. As shown in FIG. 5, the conductive substrate 202 includes the substrate 210, the barrier layer 220, and the first electrode layer 230. The same members are represented by the same symbols and are as described above. In other words, the conductive substrate 202 of the present disclosure is the structure of the solar cell 200 without the photoelectric conversion layer 240 and the second electrode layer 250 being formed. Of course, the conductive substrate 202 of the present disclosure may be applied to the solar cell 200 and may be further applied to a flat panel display (FPD). The present disclosure does not limit the application range of the conductive substrate 202, which depends on the demands of the market.

In this embodiment, the first electrode layer 230 in the present application is TCO. In addition, the topography of the second roughened surface 230a of the first electrode layer 230 in the conductive substrate 202 is formed according to the topography of the first roughened surface 220a of the barrier layer 220. Therefore, the haze of the conductive substrate 202 can be modulated accordingly.

In particular, the haze and resistance values of the barrier layer 220 and first electrode layer 230 having the structure fabricated by the process of the present disclosure are recorded in Table 1. Also, the haze and resistance of the conductive substrate 202 having a stacked structure fabricated by various conventional complicated processes are recorded. For the stacked relationship of both the conductive substrate of the present disclosure and the conventional conductive substrate, on the substrate 210, sequentially, a silicon oxide layer is formed as a barrier layer 220 and TCO is formed as an electrode layer. However, as the technology of forming the film layer is different, the microstructure on each film layer of a conventional conductive substrate might be different from the microstructure on each film layer of the conductive substrate 202 of the present disclosure.

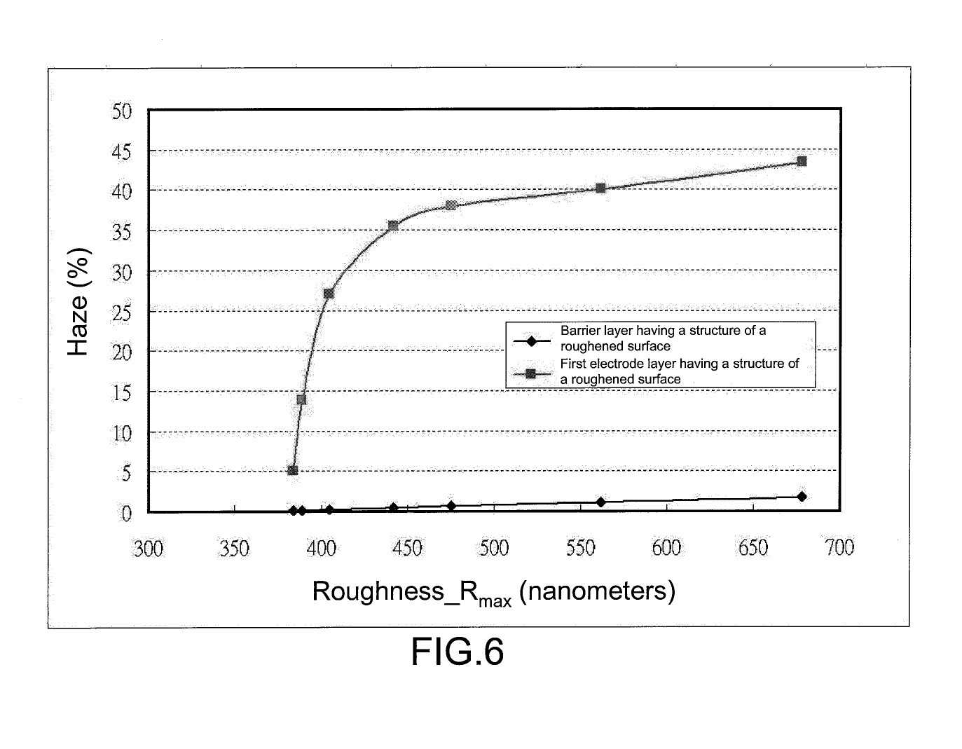

Furthermore, FIG. 6 is a chart of the relationship between haze (%) and surface roughness (Rₘₐₓ) of a barrier layer and a first electrode layer deposited at a first roughened surface 220a in a conductive substrate of the present disclosure, wherein the barrier layer 220 has a first roughened surface 220a with different roughness and the first electrode layer 230 also has a second roughened surface 230a with different roughness.

TABLE 1

| Comparison | Comparison | Comparison | Comparison | A conductive |
|---|---|---|---|---|
| of a | example 1 of | example 2 of | example 3 of | substrate 202 of |
| forming | forming a | forming a | forming a | the present |
| method of a | conductive | conductive | conductive | disclosure |
| film layer | substrate 202 in | substrate 202 in | substrate 202 in | |
| | prior art 1 | prior art 2 | prior art 3 | |
| The major | Perform etching | Form an | Form a | Form a barrier |
| technical | on a bare glass | electrode film | roughened | layer 220 |
| means used | 210 to form a | by a vacuum | surface on a | having a first |
| for forming a | roughened | sputter process | bare glass 210 in | roughened |
| roughened | surface at a | and then form | a coating | surface 220a on |
| surface | surface, so that | an electrode | manner and | a substrate 210 |
| | an electrode | layer having a | deposit a | by an |
| | layer deposited | surface of a | transparent | atmospheric |
| | thereon thus has | porous structure | conductive | pressure plasma |
| | a roughened | through wet | material on the | process, and |
| | surface. | etching. | roughened | form an |
| | | | surface. | electrode layer |
| | | | | on the first |
| | | | | roughened |
| | | | | surface 220a by |
| | | | | a vacuum |
| | | | | sputter process. |
| Resistance | 10~20 Ω/□ | smaller than | smaller than | Smaller than |
| value | | 10 Ω/□ | 10 Ω/□ | 10 Ω/□ |
| Penetration | ~75% | ~80% | ~80% | ~80% |
| Haze | ~20% | ~15% | 10~20% | 10%~40% |

As can be seen from Table 1 and FIG. 6, the conductive substrate 202 fabricated by the process in the present application has similar resistance values and penetration as in comparison examples 1 to 3. In other words, the conductive substrate 202 of the present application has the effect of simplifying the process and the haze of the conductive substrate 202 of the present application can be controlled by modulating the roughness of the second roughened surface 230a of the first electrode layer 230, so as to adapt to various application products for suitable adjustments.

Table 2 shows the relationship among roughness and haze and a first heating temperature for a conductive substrate 202 obtained when a barrier layer is fabricated by heating a substrate at a different first heating temperature before the barrier layer is formed on the substrate by the atmospheric pressure plasma process in the conductive substrate according to an embodiment of the present disclosure.

TABLE 2

| | Substrate | Surface roughness | |
|---|---|---|---|
| Experiment | temperature (° C.) | Rrms (nm) | Haze (%) |
| 1 | Room temperature | 75.556 | 1.90 |
| 2 | 50 | 89.651 | 1.70 |
| 3 | 75 | 137.730 | 1.81 |
| 4 | 100 | 148.910 | 2.35 |
| 5 | 125 | 73.791 | 0.42 |

As can be seen from Table 2 and FIG. 6, the surface characteristic of the barrier layer on the conductive substrate can be controlled by modulating the first heating temperature. Therefore, the haze of the conductive substrate 202 can also be controlled by modulating the roughness of the second roughened surface 230a of the first electrode layer 230, so as to adapt to various application products for suitable adjustments.

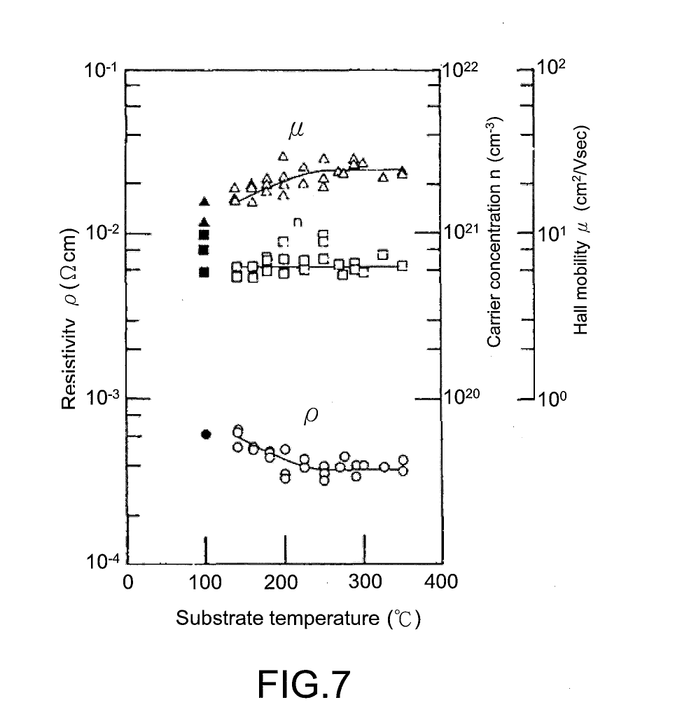

Furthermore, FIG. 7 shows the relationship between resistivity and a second heating temperature of a conductive substrate fabricated when a substrate and a barrier layer are heated at a different second heating temperature before a first electrode layer is formed on a barrier layer by a vacuum sputter process in a conductive substrate 202 according to an embodiment of the present disclosure. From the relationship between resistivity p and the second heating temperature in FIG. 7, it may be found that when the second heating temperature is higher than 250° C., the conductive substrate 202 can obtain better resistivity ρ. Furthermore, the symbols μ and n in FIG. 7 represent hall mobility and carrier concentration, respectively, and resistivity ρ can be converted from μ and n.

In conclusion, an etching process no longer requires to be performed in addition to the step of forming the barrier layer and/or the first electrode layer to obtain a first electrode layer having a roughened surface. In the application to a solar cell, the fabricated first electrode layer having the second roughened surface has the effect of limiting the light rays in the photoelectric conversion layer, so as to greatly increase the lengths of paths of the light rays transmitted in the photoelectric conversion layer, thereby enhancing the photoelectric conversion efficiency. In the fabricating method of the solar cell of the present disclosure, when a barrier layer is formed on a substrate through atmospheric pressure plasma, a first roughened surface having specific roughness is directly formed at a surface of the barrier layer. Therefore, a first electrode layer subsequently deposited thereon presents a second roughened surface in film forming of the first electrode layer according to a surface feature (topography) of the first roughened surface of the barrier layer in the process of film forming. Therefore, no etching process further requires to be performed in addition to the steps of forming the barrier layer and/or the first electrode layer to obtain the first electrode layer having the roughened surface. The fabricated first electrode layer having the roughened surface has the effect of confining a light ray in a photoelectric conversion layer, so as to greatly increase the path length of the light ray in the photoelectric conversion layer to enhance the photoelectric conversion efficiency. That is to say, in the conductive substrate of the present disclosure, with the barrier layer having the first roughened surface and the first electrode layer having the second roughened surface, the penetration of the light ray in the first electrode layer is increased and the optical length of the light ray in the photoelectric conversion layer is increased, so that the light ray is fully used in the photoelectric conversion layer to enhance the performance of the photoelectric conversion efficiency of the conductive substrate.

Furthermore, the conductive substrate of the present disclosure is applicable to a conductive substrate to enhance the performance of the photoelectric conversion efficiency of the conductive substrate.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A fabricating method of a conductive substrate, comprising:
providing a substrate;
forming a barrier layer comprising a first roughened surface on the substrate by an atmospheric pressure plasma process, wherein surface roughness Ra of the first roughened surface formed by the atmospheric pressure plasma process is between 10 nanometers (nm) and 100 nm; and
forming a first electrode layer on the barrier layer on the first roughened surface by a vacuum sputter process, wherein a surface of the first electrode layer comprises a second roughened surface, and surface roughness Ra of the second roughened surface is between 10 nm and 100 nm.

2. The fabricating method of a conductive substrate according to claim 1, further comprising heating the substrate at a first heating temperature before forming the barrier layer on the substrate by the atmospheric pressure plasma process, wherein the first heating temperature is between room temperature and 100° C.

3. The fabricating method of a conductive substrate according to claim 2, wherein the first heating temperature is between 40° C. and 70° C.

4. The fabricating method of a conductive substrate according to claim 1, further comprising heating the substrate and the barrier layer at a second heating temperature before forming the first electrode layer on the barrier layer by the vacuum sputter process, wherein the second heating temperature is between 250° C. and 450° C.

5. The fabricating method of a conductive substrate according to claim 4, wherein the second heating temperature is between 300° C. and 400° C.

6. The fabricating method of a conductive substrate according to claim 1, wherein gas used in the atmospheric pressure plasma process comprises at least one of nitrogen, oxygen, clean dry air (CDA), and mixed gas of nitrogen and oxygen.

7. The fabricating method of a conductive substrate according to claim 1, wherein a material of the barrier layer is silicon oxide, and a material of the first electrode layer comprises Al doped zinc oxide (ZnO:Al), Ga doped zinc oxide (ZnO:Ga) or Ga—Al-doped zinc oxide (ZnO:Ga,Al).

8. The fabricating method of a conductive substrate according to claim 1, further comprising:
forming a photoelectric conversion layer on the second roughened surface of the first electrode layer; and
forming a second electrode layer on the photoelectric conversion layer to obtain a solar cell.

9. A conductive substrate, comprising:
a substrate;
a barrier layer, located on the substrate, and comprising a first roughened surface, wherein surface roughness Ra of the first roughened surface is between 10 nanometers (nm) and 100 nm; and
a first electrode layer, covering the first roughened surface of the barrier layer, and comprising a second roughened surface, wherein surface roughness Ra of the second roughened surface is between 10 nm and 100 nm.

10. The conductive substrate according to claim 9, wherein a material of the barrier layer is silicon oxide.

11. The conductive substrate according to claim 9, wherein the first roughened surface comprises multiple projections, and a height of the projections is between 50 nm and 250 nm.

12. The conductive substrate according to claim 9, wherein the second roughened surface comprises multiple projections, and each projection comprises multiple micro-projections.

13. A solar cell, comprising:
a substrate;
a barrier layer, located the substrate, and comprising a first roughened surface, wherein surface roughness Ra of the first roughened surface is between 10 nanometers (nm) and 100 nm;
a first electrode layer, covering the first roughened surface of the barrier layer, and comprising a second roughened surface, wherein surface roughness Ra of the second roughened surface is between 10 nm and 100 nm;
a photoelectric conversion layer, located on the second roughened surface of conductive glass; and
a second electrode layer, located on the photoelectric conversion layer.

14. The solar cell according to claim 13, wherein a material of the barrier layer is silicon oxide.

15. The solar cell according to claim 13, wherein a thickness of the barrier layer is between 10 nm and 50 nm.

16. The solar cell according to claim 13, wherein the first roughened surface comprises multiple projections, and a height of the projections is between 50 nm and 250 nm.

17. The solar cell according to claim 13, wherein the second roughened surface comprises multiple projections, and each projection comprises multiple micro-projections.

18. The solar cell according to claim 13, wherein a material of the first electrode layer and the second electrode layer is Al doped zinc oxide (ZnO:Al), Ga doped zinc oxide (ZnO:Ga) or Ga—Al-doped zinc oxide (ZnO:Ga,Al).
